(19) United States
(12) Patent Application Publication
(10) Pub. No.: US 2015/0048396 A1
(43) Pub. Date: Feb. 19, 2015

(54) LIGHT EMITTING STRUCTURE AND SEMICONDUCTOR LIGHT EMITTING ELEMENT HAVING THE SAME

(71) Applicant: Genesis Photonics Inc., Tainan City (TW)

(72) Inventors: Jyun-De Wu, Tainan City (TW); Shen-Jie Wang, New Taipei City (TW)

(21) Appl. No.: 14/459,335

(22) Filed: Aug. 14, 2014

(30) Foreign Application Priority Data
Aug. 19, 2013 (TW) 102129696

(51) Int. Cl. H01L 33/12; H01L 33/00; H01L 33/32

(52) U.S. Cl. CPC H01L 33/12; H01L 33/32; H01L 33/0025
USPC 257/94

(57) ABSTRACT

A light emitting structure includes an N-type semiconductor layer, a P-type semiconductor layer, a light emitting layer, and a stress regulation layer. The light emitting layer is formed between the N-type semiconductor layer and the P-type semiconductor layer. The stress regulation layer is formed between the N-type semiconductor layer and the light emitting layer. The stress regulation layer comprises a plurality of pairs of AlxIn(1-x)GaN and AlyIn(1-y)GaN layers stacked with each other, wherein 0<x<1, 0≦y<1, thickness of the stress regulation layer is between 50 nanometer and 500 nanometer, and x≠y.

### BACKGROUND OF THE INVENTION

1. Field of the Invention

The present invention relates to a light emitting structure, and more particularly, to a light emitting structure having a stress regulation layer.

2. Description of the Prior Art

Since light emitting diodes (LEDs) have advantages of long service life, small size and low power consumption, the light emitting diodes are widely used in various kinds of illumination devices and display devices. Generally, the light emitting diode has a light emitting structure comprising an N type semiconductor layer, a P type semiconductor layer and a light emitting layer. The light emitting layer comprises a plurality of pairs of two specific materials stacked on each other, to be formed on the N type semiconductor layer.

However, in the light emitting structure of the light emitting diode of the prior art, The light emitting layer may have an uneven surface structure or dislocation due to huge differences in atomic arrangement direction and atomic size between the light emitting layer and the N type semiconductor layer, such that the light emitting layer has residual stress inside. The residual stress may easily cause occurrence of defect in the light emitting structure, so as to seriously affect light emission efficiency and production yield of the light emitting diode.

### SUMMARY OF THE INVENTION

The present invention provides a light emitting structure, comprising an N type semiconductor layer, a P type semiconductor layer, a light emitting layer and a stress regulation layer. The light emitting layer is formed between the N type semiconductor layer and the P type semiconductor layer. The stress regulation layer is formed between the N type semiconductor layer and the light emitting layer. The stress regulation layer comprises a plurality of pairs of an AlxIn(1-x)GaN layer and an AlyIn(1-y)GaN layer stacked on each other, wherein 0<x<1, 0≦y<1, x≠y, and thickness of the stress regulation layer is between 50 nm and 500 nm.

The present invention further provides a semiconductor light emitting element, comprising a substrate, a light emitting structure, an N type electrode and a P type electrode arranged. The light emitting structure is arranged on the substrate. The light emitting structure comprises an N type semiconductor layer, a P type semiconductor layer, a light emitting layer and a stress regulation layer. The light emitting layer is formed between the N type semiconductor layer and the P type semiconductor layer. The stress regulation layer is formed between the N type semiconductor layer and the light emitting layer. The stress regulation layer comprises a plurality of pairs of an AlxIn(1-x)GaN layer and an AlyIn(1-y)GaN layer stacked on each other, wherein 0<x<1, 0≦y<1, x≠y, and thickness of the stress regulation layer is between 50 nm and 500 nm. The N type electrode is arranged on the N type semiconductor layer. The P type electrode is arranged on the P type semiconductor layer.

In contrast to the prior art, the light emitting structure and the semiconductor light emitting element of the present invention comprise stress regulation layers for improving surface flatness of the light emitting layer during formation, in order to regulate stress generated during the formation of the light emitting layer. Therefore, the light emitting structure and the semiconductor light emitting element of the present invention have better light emission efficiency and production yields.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram showing a formation process of a light emitting structure of the present invention.

FIG. 2 is a diagram showing a formation process of the light emitting structure of the present invention.

FIG. 3 is a diagram showing a formation process of the light emitting structure of the present invention.

FIG. 4 is a diagram showing a formation process of the light emitting structure of the present invention.

FIG. 5 is a diagram showing a light emitting structure according to another embodiment of the present invention.

FIG. 6 is a diagram showing a semiconductor light emitting element of the present invention.

### DETAILED DESCRIPTION

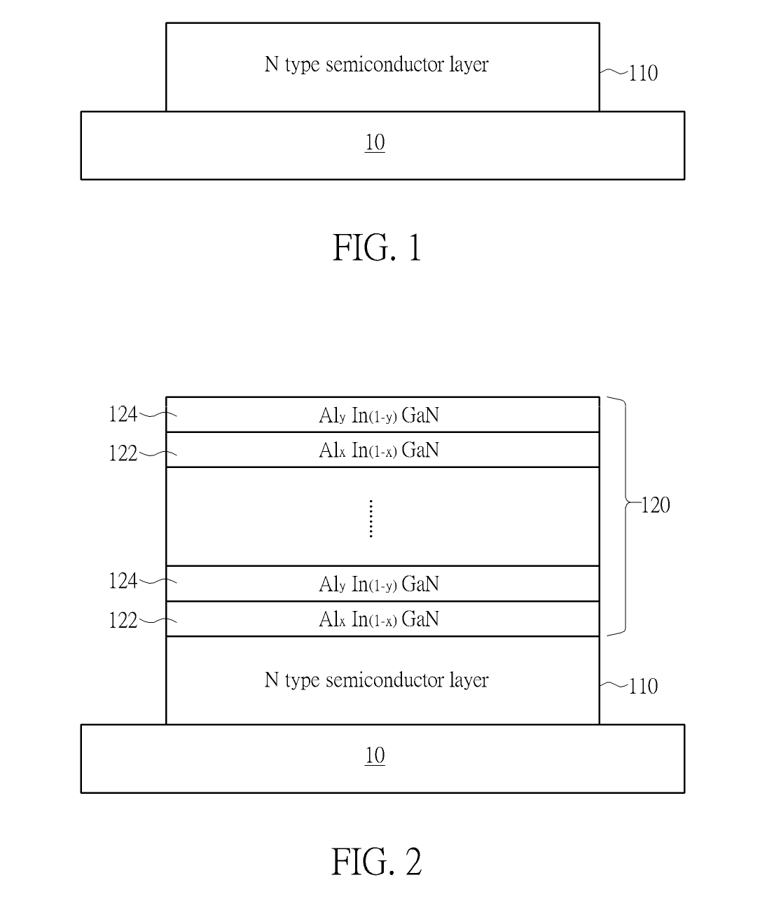

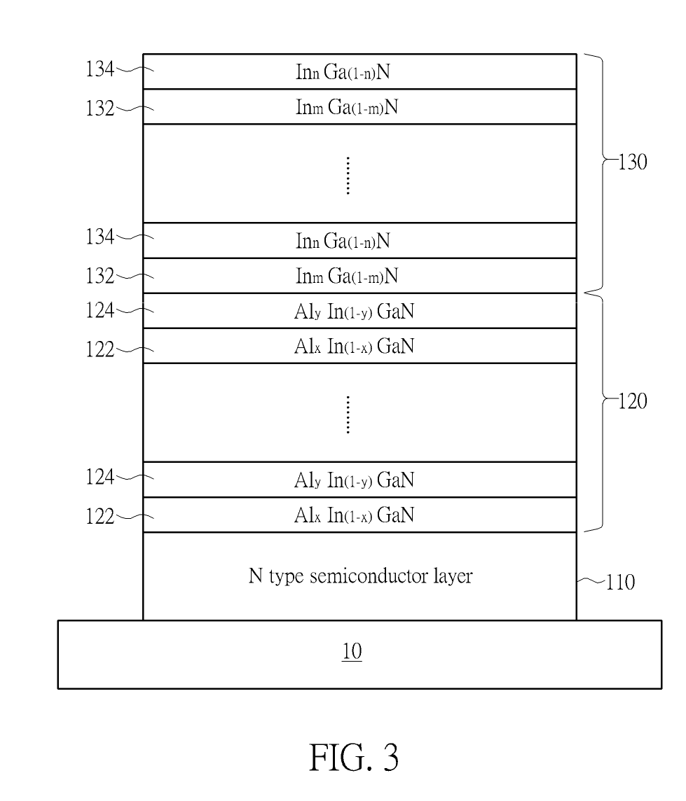

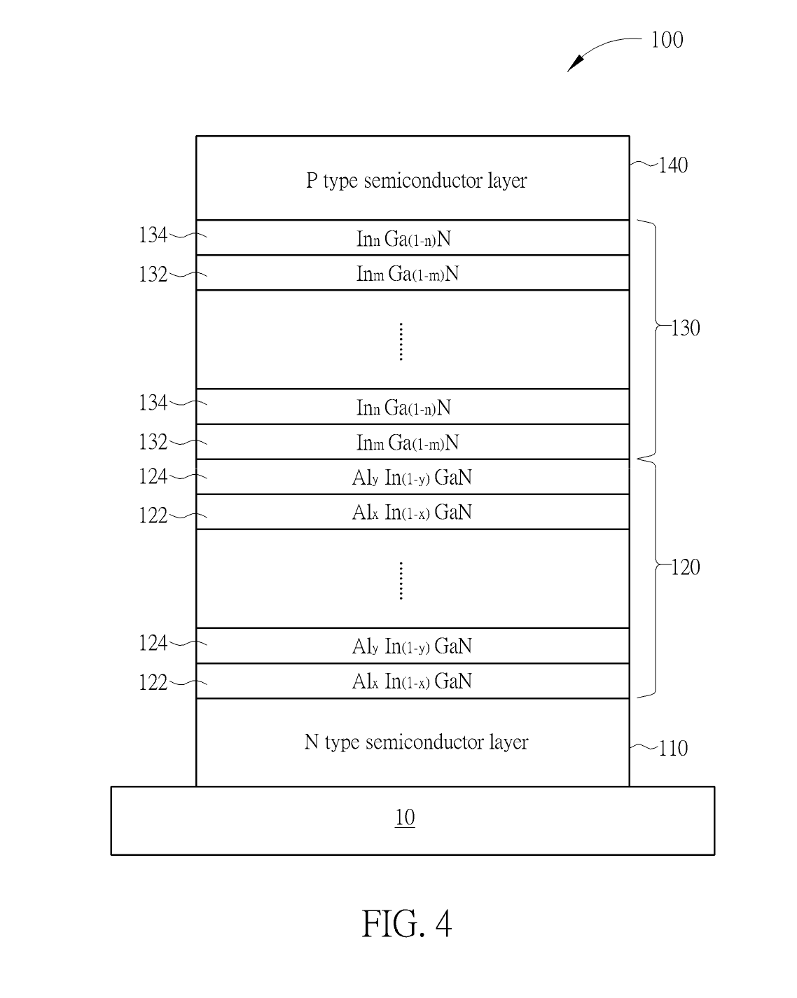

Please refer to FIG. 1 to FIG. 4. FIG. 1 to FIG. 4 are diagrams showing formation processes of a light emitting structure of the present invention. As shown in FIG. 1, an N type semiconductor layer 110 is first formed on a substrate 10. In the present embodiment, the N type semiconductor layer 110 is an N type GaN semiconductor layer. As shown in FIG. 2, after formation of the N type semiconductor layer 110, a stress regulation layer 120 is formed on the N type semiconductor layer 110. The stress regulation layer 120 comprises a plurality of pairs of an AlₓIn₍₁₋ₓ₎GaN layer 122 and an Al_{y}In_{(1-y)}GaN layer 124 stacked on each other, wherein 0<x<1, 0≦y<1, x≠y, and total thickness of the stress regulation layer 120 is between 50 nm and 500 nm. As shown in FIG. 3, after formation of the stress regulation layer 120, a light emitting layer 130 start to grow on a surface of a topmost Al_{y}In_{(1-y)}GaN layer. The light emitting layer 130 comprises a plurality of pairs of an InₘGa₍₁₋ₘ₎N layer 132 and an InₙGa₍₁₋ₙ₎N layer 134 stacked on each other, wherein m>n, and n≧0. In a pair of the InₘGa₍₁₋ₘ₎N layer 132 and an InₙGa₍₁₋ₙ₎N layer 134, the InₘGa₍₁₋ₘ₎N layer 132 is closer to the stress regulation layer 120. In addition, in a pair of the AlₓIn₍₁₋ₓ₎GaN layer 122 and the Al_{y}In_{(1-y)}GaN layer 124 of the stress regulation layer 120, the AlₓIn₍₁₋ₓ₎GaN layer 122 is closer to the N type semiconductor layer 110, and the Al_{y}In_{(1-y)}GaN layer 124 is closer to the light emitting layer 130. Moreover, in the pair of the AlₓIn₍₁₋ₓ₎GaN layer 122 and the Al_{y}In_{(1-y)}GaN layer 124, y<x, that is, the AlₓIn₍₁₋ₓ₎GaN layer 122 with a higher aluminum concentration is closer to the N type semiconductor layer 110. In a preferred embodiment, 0<y<x<1, when the stress regulation layer 120 is made of the two aluminum indium gallium nitride materials, since atomic compositions in the two aluminum indium gallium nitride materials are similar, lattices of the AlₓIn₍₁₋ₓ₎GaN layer 122 and the Al_{y}In_{(1-y)}GaN layer 124 match each other, such that stress generated after stacking is smaller, in order to reduce residual stress and epitaxial defect due to mismatch of the lattices. As shown in FIG. 4, after formation of the light emitting layer 130, a P type semiconductor layer 140 is formed on the light emitting layer 130. In the present embodiment, the P type semiconductor layer 140 is a P type GaN semiconductor layer. Thereby, a light emitting structure 100 comprising the N type semiconductor layer 110, the P type semiconductor layer 140, the light emitting layer 130 and the stress regulation layer 120 is formed.

According to the above arrangement, since the stress regulation layer 120 is made of four-member materials of AlₓIn₍₁₋ₓ₎GaN and Al_{y}In_{(1-y)}GaN, stress effect between AlₓIn₍₁₋ₓ₎GaN and Al_{y}In_{(1-y)}GaN is smaller. Therefore, when the light emitting layer 130 grows on the stress regulation layer 120, stress generated during the formation of the light emitting layer 130 can be regulated by the stress regulation layer 120, so as to improve light emission efficiency and production yield of the light emitting structure 100.

In the above embodiment, thickness of the stress regulation layer 120 is between 50 nm and 500 nm, and the stress regulation layer 120 comprises 3 to 30 pairs of the AlₓIn₍₁₋ₓ₎GaN layer 122 and the Al_{y}In_{(1-y)}GaN layer 124 stacked on each other. When the thickness of the stress regulation layer 120 is within the above range, a composition ratio of the stress regulation layer 120 can be preciously controlled during an epitaxy process, the light emitting layer 130 growing on the stress regulation layer 120 has better surface flatness. If the stress regulation layer 120 is too thick, an electron transfer path becomes longer, so as to increase possibility of the electron being restrained by defects, such that the light emission efficiency is affected, and stress accumulation is increased. Preferably, the thickness of the stress regulation layer 120 is between 150 nm and 200 nm, and the stress regulation layer 120 comprises 15 to 20 pairs of the AlₓIn₍₁₋ₓ₎GaN layer 122 and the Al_{y}In_{(1-y)}GaN layer 124, so as to match better with the light emitting layer 130. A ratio of thickness of the AlₓIn₍₁₋ₓ₎GaN layer 122 to thickness of the Al_{y}In_{(1-y)}GaN layer 124 is between 2 and 4, and thickness of each pair of the AlₓIn₍₁₋ₓ₎GaN layer 122 and the Al_{y}In_{(1-y)}GaN layer 124 is between 2 nm and 15 nm, such that the stress regulation layer 120 can provide better stress regulation effect. For example, the thickness of the AlₓIn₍₁₋ₓ₎GaN layer 122 is 7.5 nm, and the thickness of the Al_{y}In_{(1-y)}GaN layer 124 is 2.5 nm, the stress regulation layer 120 can provide better stress regulation effect to the light emitting layer 130 according to the above thickness ratio. In addition, silicon doping concentrations of the AlₓIn₍₁₋ₓ₎GaN layer 122 and the Al_{y}In_{(1-y)}GaN layer 124 are between 1×10¹⁷ cm⁻³ and 3×10¹⁸ cm⁻³, in order to increase crystallinity and conductivity of the stress regulation layer 120.

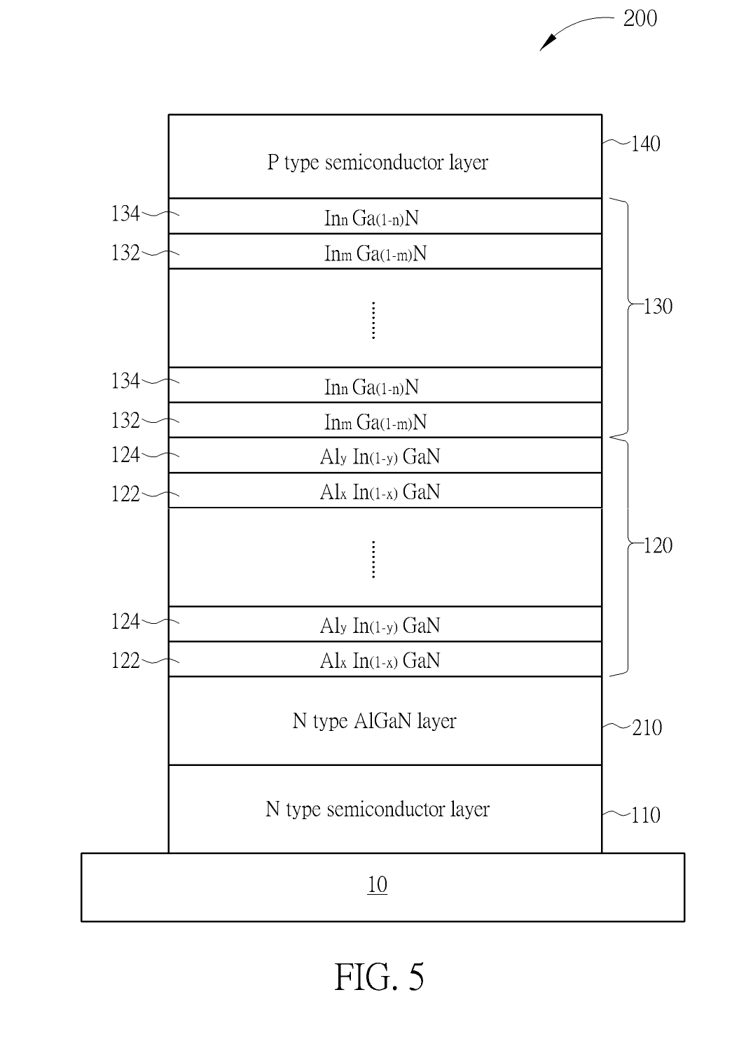

Please refer to FIG. 5. FIG. 5 is a diagram showing a light emitting structure according to another embodiment of the present invention. As shown in FIG. 5, the light emitting structure 200 of the present invention can further comprise an N type AlGaN layer 210 formed between the N type semiconductor layer 110 and the stress regulation layer 120, for being utilized as a hole blocking layer. An energy gap of the N type AlGaN layer 210 is larger than an energy gap of an AlₓIn₍₁₋ₓ₎GaN layer 122 closest to the N type semiconductor layer 110. The light emitting structure 200 of the present invention can further comprise a P type AlGaN layer (not shown) formed between the P type semiconductor layer 140 and the light emitting layer 130, for being utilized as an electron blocking layer. An energy gap of the P type AlGaN layer is larger than an energy gap of an InₙGa₍₁₋ₙ₎N layer 134 closest to the P type semiconductor layer 110. The hole blocking layer and the electron blocking layer are utilized to restrain electron hole and electron within the light emitting layer 130, in order to increase possibility of combining the electron hole and electron, for further increasing light emission efficiency. In addition, when the N type AlGaN layer 210 is added between the N type semiconductor layer 110 and the stress regulation layer 120, since the stress regulation layer 120 comprises aluminum atoms, a stress buffering effect can be provided between the N type AlGaN layer 210 and the light emitting layer 130, so as to decrease occurrence of defect during growth of lattices.

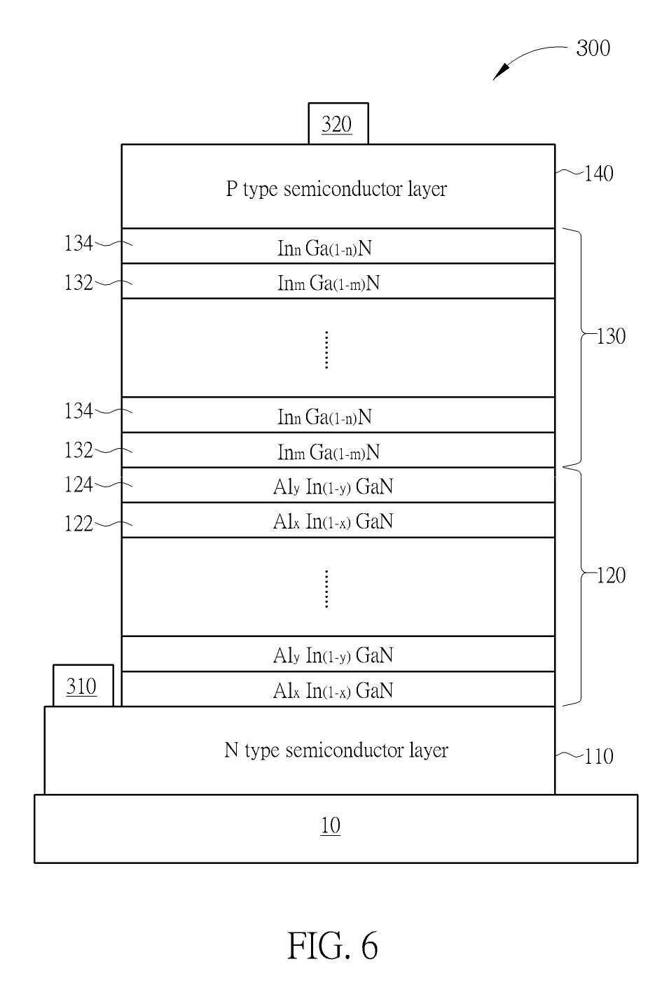

Please refer to FIG. 6. FIG. 6 is a diagram showing a semiconductor light emitting element of the present invention. As shown in FIG. 6, the semiconductor light emitting element 300 of the present invention comprises a substrate 10, a light emitting structure 100, an N type electrode 310 and a P type electrode 320. The light emitting structure of FIG. 6 can be identical to the light emitting structure shown in FIG. 4 or FIG. 5. In the embodiment of FIG. 6, the light emitting structure 100 is identical to the light emitting structure shown in FIG. 4. The N type electrode 310 is arranged on the N type semiconductor layer 110. The P type electrode 320 is arranged on the P type semiconductor layer 140. When providing power between the N type electrode 310 and the P type electrode 320, the semiconductor light emitting element 300 of the present invention is capable of emitting light.

Similarly, when forming the semiconductor light emitting element 300 of the present invention, the stress regulation layer 120 has better surface flatness. Therefore, when the light emitting layer 130 is forming on the stress regulation layer 120, stress generated during formation of the light emitting layer 130 can be regulated by the stress regulation layer 120, so as to improve light emission efficiency and production yield of the semiconductor light emitting element 300 of the present invention.

In contrast to the prior art, the light emitting structure and the semiconductor light emitting element of the present invention comprise stress regulation layers for improving surface flatness of the light emitting layer during formation, in order to regulate stress generated during the formation of the light emitting layer. Therefore, the light emitting structure and the semiconductor light emitting element of the present invention have better light emission efficiency and production yields.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A light emitting structure, comprising:
an N type semiconductor layer;
a P type semiconductor layer;
a light emitting layer formed between the N type semiconductor layer and the P type semiconductor layer; and
a stress regulation layer formed between the N type semiconductor layer and the light emitting layer, the stress regulation layer comprising a plurality of pairs of an AlₓIn₍₁₋ₓ₎GaN layer and an Al_{y}In_{(1-y)}GaN layer stacked on each other, wherein 0<x<1, 0≦y<1, x≠y, and thickness of the stress regulation layer is between 50 nm and 500 nm.

2. The light emitting structure of claim 1, wherein the light emitting layer comprises a plurality of pairs of an InₘGa₍₁₋ₘ₎N layer and an InₙGa₍₁₋ₙ₎N layer stacked on each other, wherein m>n, and n≧0.

3. The light emitting structure of claim 1, wherein the stress regulation layer comprises 3 to 30 pairs of the AlₓIn₍₁₋ₓ₎GaN layer and the Al_{y}In_{(1-y)}GaN layer stacked on each other.

4. The light emitting structure of claim 1, wherein in a pair of the AlₓIn₍₁₋ₓ₎GaN layer and the Al_{y}In_{(1-y)}GaN layer, the AlₓIn₍₁₋ₓ₎GaN layer is closer to the N type semiconductor layer, the Al_{y}In_{(1-y)}GaN layer is closer to the light emitting layer, and x>y.

5. The light emitting structure of claim 4, wherein in the pair of the AlₓIn₍₁₋ₓ₎GaN layer and the Al_{y}In_{(1-y)}GaN layer, 0<y<x<1.

6. The light emitting structure of claim 5, wherein a ratio of thickness of the AlₓIn₍₁₋ₓ₎GaN layer to thickness of the Al_{y}In_{(1-y)}GaN layer is between 2 and 4.

7. The light emitting structure of claim 1, wherein silicon doping concentrations of the AlₓIn₍₁₋ₓ₎GaN layer and the Al_{y}In_{(1-y)}GaN layer are between 1×10¹⁷ cm⁻³ and 3×10¹⁸ cm⁻³.

8. The light emitting structure of claim 1, wherein thickness of each pair of the AlₓIn₍₁₋ₓ₎GaN layer and the Al_{y}In_{(1-y)}GaN layer is between 2 nm and 15 nm.

9. A semiconductor light emitting element, comprising:
a substrate;
a light emitting structure of claim 1 arranged on the substrate;
an N type electrode arranged on the N type semiconductor layer; and
a P type electrode arranged on the P type semiconductor layer.
